(19) United States
(12) Patent Application Publication
(10) Pub. No.: US 2010/0164543 A1
(43) Pub. Date: Jul. 1, 2010

(54) LOW-COMPLEXITY ELECTRONIC ADDER CIRCUITS AND METHODS OF FORMING THE SAME

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/643,287

(22) Filed: Dec. 21, 2009

Related U.S. Application Data
(60) Provisional application No. 61/204,075, filed on Dec. 31, 2008.

(51) Int. Cl. H03K 19/21; G11C 11/00; H01L 21/98; G06F 7/50

(52) U.S. Cl. 326/53; 365/163; 29/846; 438/129; 708/700; 257/E21.705

(57) ABSTRACT

In various embodiments, an adder circuit includes a plurality of transistors, all of the transistors being of a single type selected from the group consisting of NMOS transistors and PMOS transistors, and dissipates no more power than an equivalent CMOS circuit.

### CROSS-REFERENCE TO RELATED APPLICATION

This application claims priority to and the benefit of, and incorporates herein by reference in its entirety, U.S. Provisional Patent Application No. 61/204,075, which was filed on Dec. 31, 2008.

### TECHNICAL FIELD

In various embodiments, the present invention relates to electronic circuits such as adders, and in particular to electronic circuits fabricated with a minimum number of different component types.

BACKGROUND

The prior art is replete with different versions of electronic circuits that perform arithmetic functions, and their sizes and complexities vary widely. One general design principle for simple circuits is minimizing the total number of constituent parts (i.e., components) utilized to form the circuit. As most, if not all, electronic circuits are eventually implemented in tangible form as, e.g., solid-state integrated circuit chips, costs ordinarily diminish as the number of components decreases, since the chip area decreases concomitantly. However, with individual transistor gate lengths being reduced to 0.1 μm and below, reducing the total number of process steps required to fabricate the chip can be more important than reducing the absolute number of components thereon. Moreover, regardless of the number of devices in a circuit, the number of process steps necessary to fabricate the circuit may be minimized by limiting the number of different types of devices therein.

FIGS. 1A and 1B depict different designs for a simple inverter circuit. FIG. 1A depicts an inverter designed in a typical n-type metal-oxide-semiconductor (NMOS) transistor technology, i.e., utilizing only NMOS field-effect transistors (FETs). Transistor Q1 is in a pull-up configuration and operates in a manner similar to that of a simple pull-up resistor. When input A is in a low logic state, transistor Q2 is turned off, the output Ā is dominated by the signal voltage (depicted as +) through pull-up transistor Q1, and the output Ā is placed in a high logic state. Conversely, when the input A is in a high logic state, transistor Q2 is turned on, the output Ā is dominated by the signal voltage through transistor Q2 to ground, and the output Ā is placed in a low logic state. An important shortcoming of this NMOS-only inverter circuit is its significant steady-state power dissipation through pull-up transistor Q1 when the input A is high and the output Ā is low. The power consumption (and associated heat dissipation) of more complex circuits incorporating NMOS-only inverters may be prohibitive.

Complementary metal-oxide-semiconductor (CMOS) technology, utilizing both NMOS and p-type metal-oxide-semiconductor (PMOS) transistors, has been used to combat the above-described power dissipation issue. FIG. 1B depicts an inverter designed in a typical CMOS technology. PMOS transistor Q1 is in a pull-up configuration and operates in a “complementary” fashion to NMOS transistor Q2. When the input A is in a low logic state, transistor Q1 is turned on, transistor Q2 is turned off, and the output Ā is pulled high through transistor Q1. Conversely, when input A is in a high logic state, transistor Q1 is turned off, transistor Q2 is turned on, and the output Ā is pulled low through transistor Q2 to ground. Since PMOS transistor Q1 and NMOS transistor Q2 are never both turned on at the same time, a steady current is never drawn through transistors Q1 and Q2, and power dissipation is minimized by limiting it to the charging and discharging of various circuit features (e.g., the MOS gates and parasitic capacitances of the wires). However, this advantage comes with a price. Since fabrication of NMOS and PMOS transistors must be performed separately (as they include, e.g., different source, drain, and well doping, as well as the associated photolithography steps), the processing cost of CMOS circuits is generally much higher.

As described above, typical low-complexity circuit designs (where the term “low-complexity” is utilized herein to refer to designs utilizing a minimum number of different types of constituent components) suffer from, e.g., high power dissipation. Unfortunately, strategies for reducing power dissipation typically involve the introduction of higher complexity, thus increasing the processing and overall costs of integrated-circuit chips. Accordingly, there exists a need for electronic arithmetic-circuit designs that both minimize power consumption and utilize a minimal number of different component types.

### SUMMARY

Embodiments of the present invention include electronic circuit blocks, e.g., adders, designed with low complexity. Such circuit blocks are preferably designed with only one type of transistor (i.e., either NMOS or PMOS), and may also include at least one type of simple current-steering device (e.g., diodes, field emitters, etc.). The current-steering device may be a transistor (typically of the same one type) that is configured as a diode, e.g, has its drain and gate connected. The circuit blocks incorporate the low power dissipation of CMOS technology while minimizing processing (and thus overall manufacturing) costs by limiting the total number of constituent component types. Advantageously, embodiments of the present invention have little or no static power consumption, as current flows therethrough only during state switching.

In an aspect, embodiments of the invention feature an electronic device including an adder circuit having a plurality of transistors, all of which are of a single type selected from the group consisting of NMOS transistors and PMOS transistors. The adder circuit dissipates no more power than an equivalent CMOS circuit. The adder circuit may include or consist essentially of a half adder and/or a full adder, and may include a plurality of current-steering devices. Each of the current-steering devices may include or consist essentially of a diode. The adder circuit may include or consist essentially of a plurality of stages, and all but one of the stages may be substantially identical. The adder circuit may include at least one transistor configured to function as a capacitor. The static power consumption of the adder circuit may be approximately zero.

In another aspect, embodiments of the invention feature a memory device including or consisting essentially of a memory array and an adder circuit electrically connected to the memory array. The memory array includes or consists essentially of a plurality of generally parallel rows and a plurality of generally parallel columns intersecting the plurality of rows. A memory cell including or consisting essentially of a resistive-change material is proximate an intersection of a row and a column. The adder circuit includes or consists essentially of a plurality of transistors. All of the transistors of the adder circuit are either PMOS transistors or NMOS transistors. The resistive-change material may include or consist essentially of a chalcogenide alloy, which may include germanium, antimony, and/or tellurium. The adder circuit may include or consist essentially of a half adder and/or a full adder. The memory cell may include a current-steering element, which may be in series with the resistive-change material. The power dissipation of the memory device may be no more than the power dissipation of an equivalent memory device including a CMOS adder. The static power consumption of the adder may be approximately zero.

In yet another aspect, embodiments of the invention feature a method of forming an electronic device. An adder circuit including a plurality of transistors is provided, all of which are of a single type selected from the group consisting of NMOS transistors and PMOS transistors. The adder circuit dissipates no more power than an equivalent CMOS circuit.

In another aspect, embodiments of the invention feature a method of forming an electronic device including performing a plurality of process steps to form an adder circuit. The adder circuit includes or comprises essentially of a plurality of transistors. The number of process steps is less than the number of process steps required to fabricate an equivalent CMOS adder circuit. All of the transistors in the adder circuit may be only either NMOS or PMOS transistors.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1A and 1B are circuit diagrams of prior-art inverters utilizing NMOS technology (FIG. 1A) and CMOS technology (FIG. 1B);

FIGS. 2 and 3 are circuit diagrams of half (FIG. 2) and full (FIG. 3) adder circuits designed in accordance with embodiments of the invention;

FIG. 4 is an exemplary timing diagram of the operation of adder circuits designed in accordance with embodiments of the present invention; and

FIG. 5 is a table of the logic states for an adder circuit designed in accordance with embodiments of the present invention; and

FIG. 6 is a circuit diagram of a six-stage adder circuit designed in accordance with embodiments of the present invention.

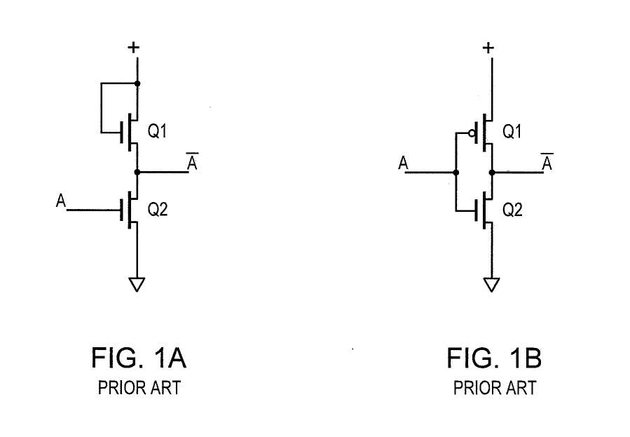

### DETAILED DESCRIPTION

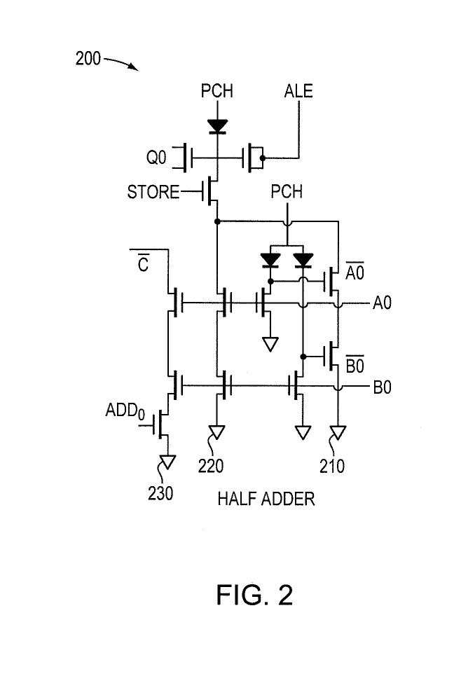

FIG. 2 depicts a half adder circuit 200 (all of the transistors of which are NMOS field-effect transistors) designed according to embodiments of the present invention. Operation of half adder 200 commences with a high voltage level applied to the precharge input (depicted as PCH). The voltage passes through each of three diodes (or other current-steering devices) and places a charge on the gates of output transistor Q0 and transistors A̅0̅ and B̅0̅. The voltage is large enough to fully turn on the transistors by charging their gates while allowing for the voltage drop across each of the three PCH diodes. In some embodiments, output transistor Q0 may have to switch a higher voltage; thus, depicted in FIG. 2 is an optional charge boost transistor (here configured as a capacitor) provided to capacitively boost the voltage on the gate of output transistor Q0 when ALE is raised to high voltage. Once the gate of output transistor Q0 is charged, it should not be exposed to a discharge path until the A0 and B0 inputs and the rest of the half adder circuit 200 have settled. Hence, the gating STORE transistor is generally turned off until the half adder circuit 200 has settled.

FIG. 2 depicts three paths to ground. Path 210 corresponds to the case when both the A0 and B0 inputs are at low voltage. In such embodiments, the A0 input remains low (its state at the start of operation and whenever PCH is high), and the A̅0̅ transistor remains charged and switched on. Also, B0 stays low (its state at the start of operation and whenever PCH is high), and the B̅0̅ transistor remains charged and switched on. With both A̅0̅ and B̅0̅ transistors remaining turned on, a path from the bottom of the STORE transistor to ground is present that will turn off output transistor Q0 when STORE is asserted high. As a result, when A0 and B0 are low (i.e., at values of zero), the addition of these two bits will result in a zero output (i.e., Q0 turned off).

Path 220 corresponds to the case when both the A0 and B0 inputs are high. In this case, the A0 and B0 inputs are at high voltage, and a path from the bottom of the STORE transistor to ground is present that will turn off output transistor Q0 when STORE is asserted high. As a result, when A0 and B0 are high (i.e., at values of one), the addition of these two bits will result in a zero output (i.e., Q0 turned off). Furthermore, when both A0 and B0 are high, the path 230 (corresponding to the CARRY OUT output (depicted as C̅) that is asserted low) will be completed to ground when the ADD₀ input, which controls the propagation of the carry signal in half adder circuit 200, goes to high voltage. As a result, when A0 and B0 are high (i.e., ones), the addition of these two bits will result in a zero output (i.e., Q0 turned off) along with the CARRY OUT output asserted. In various embodiments, the number of add stages is increased, and the circuit portion for controlling the CARRY OUT signal is constructed with larger (e.g., having larger width) transistors in order to conduct more current.

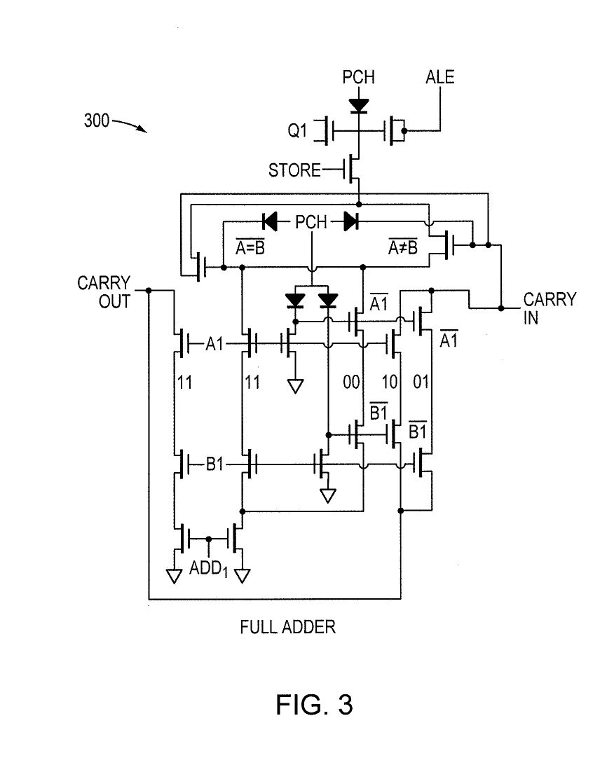

FIG. 3 depicts a full adder circuit 300 (all of the transistors of which are NMOS field-effect transistors) designed according to embodiments of the present invention. Operation of full adder 300 commences with a high voltage applied to the precharge input (depicted as PCH). The voltage passes through each of three PCH diodes (or other current-steering devices) and places a charge on the gates of output transistor Q1, the two A̅1̅ transistors, and the two B̅1̅ transistors. The voltage is large enough to fully turn on the transistors by charging their gates while allowing for the voltage drop across each of the three PCH diodes. PCH also charges the A̅=̅B̅ pass transistor and the A̅≠̅B̅ pass transistor through two additional diodes. In some embodiments, output transistor Q1 may have to switch a higher voltage; thus, depicted in FIG. 3 is an optional charge boost transistor (here configured as a capacitor) to capacitively boost the voltage on the gate of Q1 when ALE is raised to a high voltage. Once the gate of Q1 is charged, it should not be exposed to a discharge path until the A1 and B1 inputs, the CARRY IN input, and the rest of full adder 300 have settled. Hence, the gating STORE transistor is generally turned off until full adder 300 has settled.

FIG. 3 depicts five “columnar” current paths (that ultimately go to ground, as described below)—one at the far left for the CARRY OUT output and one each for the four permutations of the A1 and B1 inputs (labeled as 11, 00, 10, and 01). There are two other transistors between the 11 column path and the 00 column path. One transistor has its gate connected to the A1 input, and one has its gate connected to the B1 input; these transistors are used to discharge the A̅1̅ transistor and the B̅1̅ transistors, respectively, which generates paths corresponding to the inputs inverted.

Path 01 in FIG. 3 corresponds to the case when the A1 input is low (i.e., zero) and the B1 input is high (i.e., one). In this case, A1 stays low (its state at the start of operation and whenever PCH is high) and the A̅1̅ transistor remains charged and switched on. Also, B1 goes high and turns on its corresponding transistor to complete the circuit of path 01. With both A̅1̅ and B1 transistors remaining turned on, a path from the CARRY IN input to the CARRY OUT output is formed. Thus, when one of the input bits (here B1) is one (TRUE) and the CARRY IN input is asserted (TRUE), the CARRY OUT output is asserted, as required for proper operation. In other words, path 01 allows an asserted CARRY IN input to be connected to the CARRY OUT output, thus asserting that output.

Similarly, path 10 in FIG. 3 corresponds to the case when the B1 input is low (i.e., zero) and the A1 input is high (i.e., one). In this case, B1 stays low (its state at the start of operation and whenever PCH is high), and the B̅1̅ transistor remains charged and switched on. Also, A1 goes high and turns on its corresponding transistor to complete the circuit of path 10. With both B̅1̅ and A1 transistors remaining turned on, a path from the CARRY IN input to the CARRY OUT output is formed. This corresponds to the condition when one of the input bits (here A1) is one (TRUE) and the CARRY IN input is asserted (TRUE and pulling to ground), resulting in the CARRY OUT output being asserted, as required for proper operation. In other words, path 10 allows an asserted CARRY IN input to be connected to the CARRY OUT output, thus asserting that output.

Notably, when A1 and B1 are both one (i.e., TRUE) or both zero (i.e., FALSE), the CARRY IN input is not connected to the CARRY OUT output through either path 01 or path 10. In other words, CARRY IN has no impact on CARRY OUT when A1 and B1 are in the same state (i.e., when A1=B1)—if both A1 and B1 are zeros, there is no carry regardless of the state of the CARRY IN input, and when both A1 and B1 are ones, the CARRY OUT output will be asserted regardless of the state of the CARRY IN input.

When both A1 and B1 are ones, the leftmost columnar path (corresponding to the CARRY OUT output, which is asserted low) will be completed to ground when the ADD₁ input, which controls the propagation of the carry signal in full adder 300, goes high. In various embodiments, the number of add stages is increased, and the leftmost column for controlling the CARRY OUT signal is constructed with larger (e.g., having larger width) transistors in order to conduct more current.

As stated above, the PCH input charges the A̅=̅B̅ pass transistor and the A̅≠̅B̅ pass transistor through two diodes (or other current-steering devices). When the gate of the A̅=̅B̅ pass transistor is charged, it connects the CARRY IN input to the bottom of the gating STORE transistor. When both A1 and B1 inputs are ones, path 11 is connected to ground (when the ADD₁ input, which controls the propagation of the carry signal in full adder 300, goes high), thus discharging the gate of the A̅=̅B̅ pass transistor to ground. When both A1 and B1 inputs are zeros, the gate of the A̅=̅B̅ pass transistor is discharged to ground through path 11 when the ADD₁ input goes high. In other words, when the A1 input shares the same state as the B1 input, the gate of the A̅=̅B̅ pass transistor is connected to ground (hence the name A̅=̅B̅ for this transistor).

If the A1 input and the B1 input do not share the same state, the gate of the A̅=̅B̅ pass transistor remains charged and the A̅=̅B̅ pass transistor remains switched on, thus connecting the CARRY IN input to the bottom of the gating STORE transistor. In other words, one of A1 and B1 is a one and the other is a zero, the output is discharged if the CARRY IN input is asserted (since a single one bit and a one carried in adds to a zero bit on the output and the carry out being asserted). When only one input is a one bit, and if CARRY IN is a one bit (asserted low to ground), the Q1 output transistor is discharged, resulting in a zero bit at the output after STORE goes high. If the A̅=̅B̅ pass transistor is switched off (i.e., if its gate is grounded), then the A̅≠̅B̅ pass transistor connects the bottom of the STORE FET to ground (i.e., to the gate of the A̅=̅B̅ pass transistor, but only after ADD₁ is asserted) when CARRY IN is not asserted. In other words, the output is discharged to zero (after STORE is asserted) if A1 is equal to B1 and there is no carry. In this case, the gate of the A̅≠̅B̅ pass transistor is discharged (to the CARRY IN input), and no path will be connected to the bottom of the STORE FET. Thus, the output will remain asserted (i.e., a one), as the gate to output transistor Q1 will remain charged.

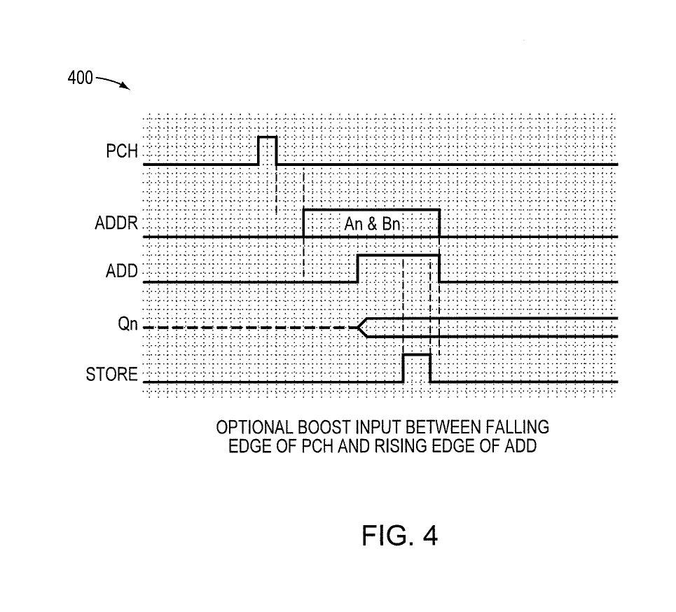

FIG. 4 shows a timing diagram 400 for one full adder stage of full adder 300. In FIG. 4, the PCH pulse terminates prior to the assertion of the A and B inputs and the ADD input is delayed following the assertion of the A and B inputs, thus giving the circuit time to settle. In this type of adder circuit (referred to as a “ripple-carry adder”), the carry signal is given time to propagate through the entire adder circuit before the STORE input is asserted. The A and B inputs and the ADD input are held until after the end of the STORE pulse.

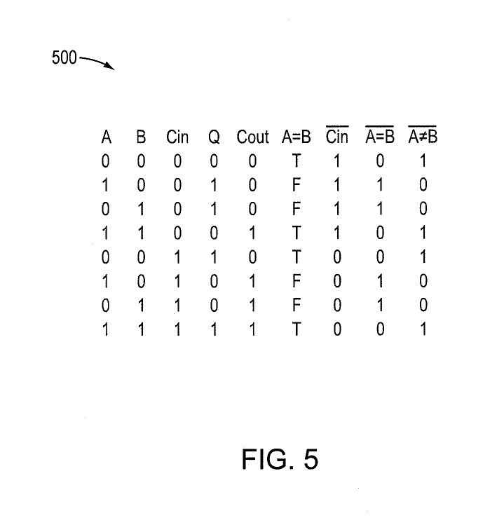

FIG. 5 depicts a table 500 of the logic states for full adder circuit 300. The output Q is equal to CARRY IN (depicted here as Cin) when inputs A and B are both one bits or when A and B are both zero bits. The output Q is equal to the complement of CARRY IN when A and B are in different states (i.e., one is a zero bit and one is a one bit). CARRY OUT (depicted here as Cout) is asserted when A and B are both one bits, and CARRY OUT is not asserted when A and B are both zero bits. If A and B are in different states, CARRY OUT is equal to CARRY IN.

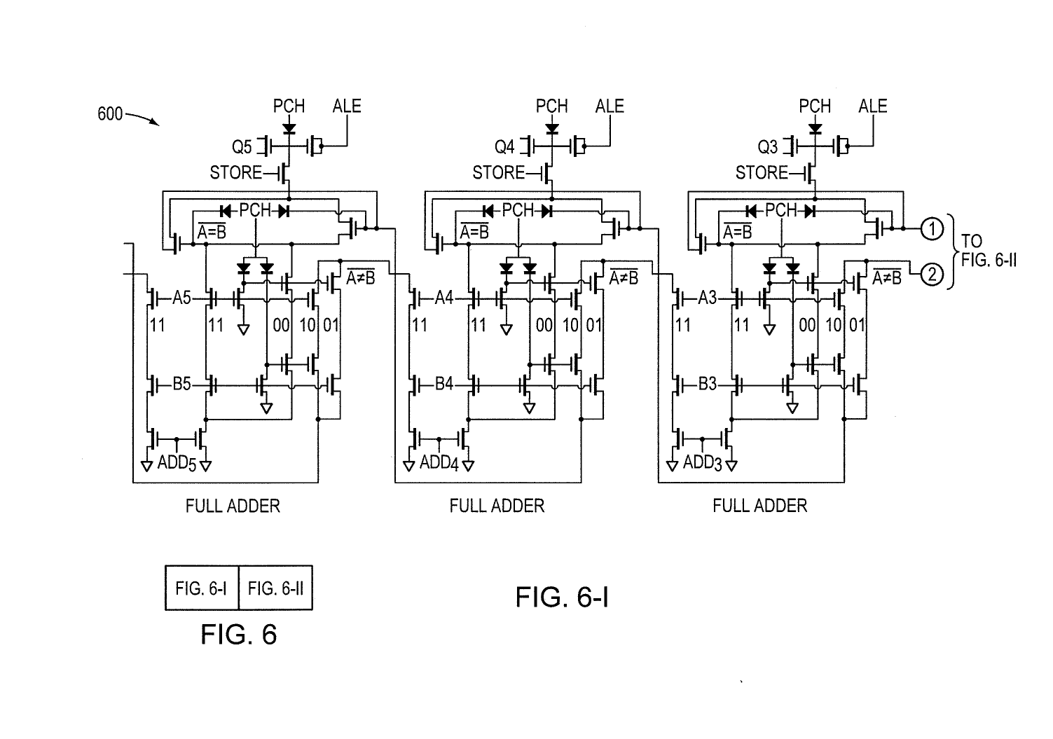

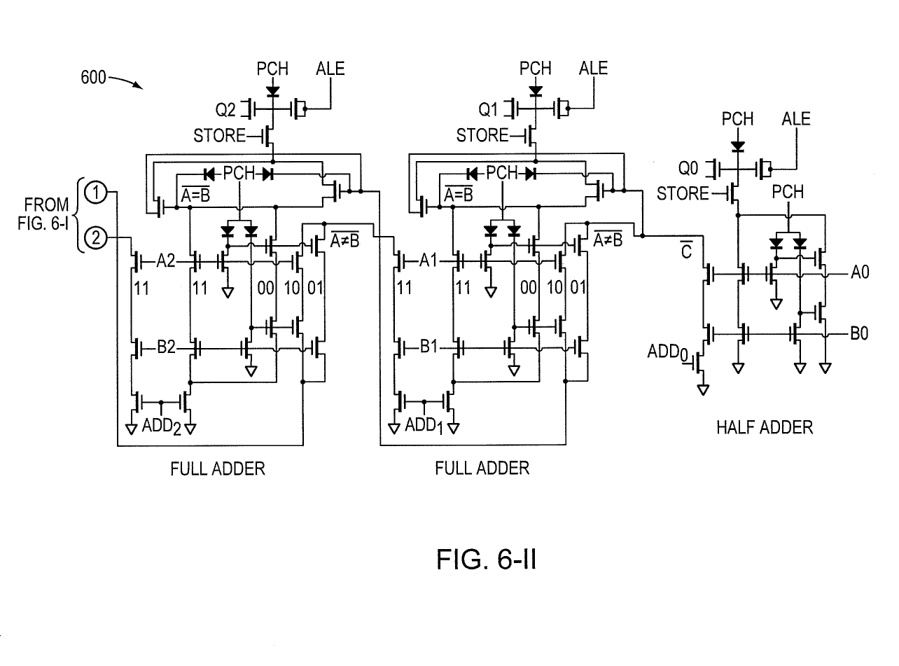

FIG. 6 depicts a six-stage adder circuit 600 (all of the transistors of which are NMOS field-effect transistors) designed according to embodiments of the present invention. In six-stage adder 600, the carry bit ripples from the lowest-order bit stage to the highest. In other words, the lowest-order bit add (in the half adder stage) is determined first, and then the carry out is available to the second-bit adder (the first full adder stage on the right side, next to the half adder stage). The second-bit adder is then calculated, and then the carry out becomes available to the third-bit adder (the next full adder stage), which is then calculated, etc. In six-stage adder 600, none of the charged transistor gates is discharged until its final state is known with certainty, because once the PCH signal is raised and then lowered, there is no source for recharging any gate charged by PCH. Similarly, the bit inputs An and Bn (labeled A0-A5 and B0-B5) are asserted high to enable the internal paths within each adder stage and the carry is asserted low to complete the discharge of transistor gates according to that stage's sum. For proper operation, the input bits of a particular stage are asserted and are allowed to settle before the carry ripples in (this is ensured by the ADDₙ input of each stage). To assert the ADD input of a particular stage, that ADD input arrives after the carry bit arrives (i.e., ripples in). So, the input ADDₙ is typically delayed by at least the amount of time that it takes for the carry bit to ripple through that stage before the signal at ADDₙ reaches the next input ADDₙ₊₁. Also, the STORE input is not asserted until the carry has rippled past that particular stage. In an embodiment, all STORE inputs are wired together and asserted after the carry has rippled all the way through and all stages of six-stage adder 600 have settled.

The circuits of FIGS. 2, 3, and 6 are depicted as including only NMOS transistors, but they may be fabricated with only PMOS transistors and operated with negative voltages (with respect to the ground voltage). Fabrication of circuits in accordance with embodiments of the present invention generally requires fewer process steps than fabrication of equivalent CMOS circuits (i.e., equivalent circuits containing both NMOS and PMOS devices). For example, a fabrication process for a device containing only NMOS devices typically omits process steps such as n-well formation; PMOS source/drain implantation and anneal; PMOS source/drain extension implantation and anneal; PMOS gate patterning, doping, and anneal; as well as the several photolithography-related process steps related to any of these. By eliminating one of the device types of a CMOS design (e.g., eliminating the PMOS devices while retaining the NMOS devices), the number of process steps is typically decreased by half or more, as is the manufacturing cost. In a preferred embodiment, each of the transistors is substantially identical to the others except for a size parameter, e.g., length and/or width. For example, transistors may have different widths in order to control and conduct different amounts of current, but may be fabricated (preferably all in parallel) by substantially the same process otherwise. Moreover, the diodes depicted in these figures may be replaced with other rectifying devices (e.g., vacuum tubes or other current-steering elements such as field emitters). Adders (e.g., half adders, full adders, and multiple-stage adders) and other circuits fabricated in accordance with embodiments of the present invention preferably dissipate no more power than (e.g., approximately the same amount of or less power than) equivalent circuits fabricated in CMOS technology (i.e., conventional equivalent circuits including both NMOS and PMOS transistors).

Embodiments of the present invention may be utilized in memory devices that include cross-point memory arrays, e.g., memory arrays such as those described in U.S. Pat. Nos. 5,889,694 and 7,548,454, as well as in U.S. Patent Application Publication No. 2009/0109726, the entire disclosure of each of which is hereby incorporated by reference. The memory array and associated circuitry (including, e.g., adders fabricated in accordance with embodiments of the invention) may be implemented with only a single type (e.g., NMOS or PMOS) of transistor. The memory array may be one of a plurality of “tiles” or sub-arrays of a larger memory array, or may be a layer (or portion of a layer) in a three-dimensional memory array that may be fabricated in accordance with U.S. Pat. No. 6,956,757, the entire disclosure of which is hereby incorporated by reference. The storage cells of the memory array may include at least one transistor (preferably a transistor of the same type as that used to construct the adder), field emitter, diode, four-layer diode, gated four-layer diode (thyristor), and/or any other device that conducts current asymmetrically at a given applied voltage. The storage elements may be fuses, antifuses, and/or devices including a resistive-change material, which may be a phase-change material such as a chalcogenide (or other material capable of programmably exhibiting one of two or more resistance values). The resistive-change material may be placed in series with a diode (or other rectifier or current-steering device) at a memory cell location. The resistive-change material may include or consist essentially of an alloy of germanium, antimony, and tellurium (GST). The combination of a single type of transistor for adder circuits with the high-density structure of a resistive-change diode cross-point memory cell has very favorable economics as a consequence of the fewer number of processing steps required. Other storage elements may also be used, including magnetic (for MRAM) and mechanical (for MEMS devices).

The storage element may even include a field-emitter programming element whose resistance and/or volume is changeable and programmable, e.g., a device described in U.S. Patent Application Publication Nos. 2007/0247890 or 2009/0161420, the entire disclosures of which are hereby incorporated by reference. The storage cells and/or storage elements may be present at or near one or more intersections between a row and a column, and may even be present at all such intersections. In an embodiment, various intersections may even include different types of storage cells or elements. In various embodiments, memory devices may include one or more layers of storage cells and/or storage elements, and the memory array(s) of any layer may include one or more sub-arrays or tiles. The memory devices may even have three-dimensional topologies.

Memory devices constructed according to embodiments of the present invention will find applicability in such areas as storing digital text, digital books, digital music, digital audio, digital photography (wherein one or more digital still images can be stored including sequences of digital images), digital video, and digital cartography (wherein one or more digital maps can be stored), as well as any combinations thereof. These devices may be embedded, removable, or removable and interchangeable among devices. They may be packaged in any variety of industry standard form factors including Compact Flash, Secure Digital, MultiMedia Cards, PCMCIA Cards, Memory Stick, any of a large variety of integrated circuit packages including Ball Grid Arrays, Dual In-Line Packages (DIPs), SOICs, PLCC, TQFPs and the like, as well as in custom-designed packages. These packages may contain just the memory chip, multiple memory chips, one or more memory chips along with a controller or other logic devices or other storage devices such as PLDs, PLAs, micro-controllers, microprocessors, controller chips, or chip-sets or other custom or standard circuitry.

Memory devices constructed according to embodiments of the present invention will also find applicability in such areas as solid state disk drives (SSD). These SSDs may include one or more memory devices and may also be combined with a controller device (including, e.g., control circuitry as described above).

Embodiments of the present invention may also be utilized with, and contain essentially only the same type of transistor as, the electronic circuits such as latches and sequencers disclosed in U.S. Patent Application Publication No. 2009/0257269, the entire disclosure of which is incorporated by reference herein.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An electronic device comprising:
an adder circuit comprising a plurality of transistors of a single type selected from the group consisting of NMOS transistors and PMOS transistors,
wherein the adder circuit dissipates no more power than an equivalent CMOS circuit.

2. The electronic device of claim 1, wherein the adder circuit comprises at least one of a half adder or a full adder.

3. The electronic device of claim 1, further comprising a plurality of current-steering devices.

4. The electronic device of claim 3, wherein each of the current-steering devices comprises a diode.

5. The electronic device of claim 1, wherein the adder circuit comprises a plurality of stages.

6. The electronic device of claim 5, wherein all but one of the stages are substantially identical.

7. The electronic device of claim 1, wherein the adder circuit comprises a transistor configured to function as a capacitor.

8. The electronic device of claim 1, wherein a static power consumption of the adder circuit is approximately zero.

9. A memory device comprising:
a memory array comprising a plurality of generally parallel rows and a plurality of generally parallel columns intersecting the plurality of rows;
a memory cell proximate an intersection of a row and a column, the memory cell comprising a resistive-change material; and
an adder circuit electrically connected to the memory array, the adder circuit comprising a plurality of transistors;
wherein all of the transistors of the adder circuit are of a single type selected from the group consisting of PMOS transistors and NMOS transistors.

10. The memory device of claim 9, wherein the resistive-change material comprises a chalcogenide alloy.

11. The memory device of claim 10, wherein the chalcogenide alloy comprises at least one of germanium, antimony, or tellurium.

12. The memory device of claim 9, wherein the adder circuit comprises at least one of a half adder or a full adder.

13. The memory device of claim 9, wherein the memory cell comprises a current-steering element.

14. The memory device of claim 13, wherein the resistive-change material and current steering element are in series.

15. The memory device of claim 9, wherein a power dissipation of the memory device is no more than a power dissipation of an equivalent memory device comprising a CMOS adder.

16. The memory device of claim 9, wherein a static power consumption of the adder circuit is approximately zero.

17. A method of forming an electronic device, the method comprising:
providing an adder circuit comprising a plurality of transistors, all of the transistors being either NMOS transistors or PMOS transistors,
wherein the adder circuit dissipates no more power than an equivalent CMOS circuit.

18. A method of forming an electronic device, the method comprising:
performing plurality of process steps to form an adder circuit, the adder circuit comprising a plurality of transistors,
wherein number of process steps is less than a number of process steps required to fabricate an equivalent CMOS circuit.

19. The method of claim 18, wherein all of the transistors in the adder circuit are NMOS transistors.

20. The method of claim 18, wherein all of the transistors in the adder circuit are PMOS transistors.
